(19) United States
(12) Patent Application Publication
(10) Pub. No.: US 2010/0193008 A1
(43) Pub. Date: Aug. 5, 2010

(54) Electrical Connection System For Photovoltaic Solar Installations

(76) Inventor: Joachim Zapf, Limburgerhof (DE)

Correspondence Address: BARLEY SNYDER, LLC, 1000 WESTLAKES DRIVE, SUITE 275, BERWYN, PA, 19312, US

(21) Appl. No.: 12/702,924

(22) Filed: Feb. 9, 2010

Related U.S. Application Data
(63) Continuation of application No. PCT/EP2008/006379, filed on Aug. 1, 2008.

(30) Foreign Application Priority Data
Aug. 10, 2007 (DE) 102007037797.7

(51) Int. Cl. H01L 31/042; H05K 7/00

(52) U.S. Cl. 136/244; 361/735

(57) ABSTRACT

A kit for an electrical connection system for photovoltaic solar installations, which includes a plurality of solar cells each with their own electrical connection. The kit includes a number of modules having a plurality of different module types, in each of which different components of the connection system are accommodated. The kit includes at least one module type, having with a connecting device for connecting the external electrical connection of one of the solar cells. A plurality of the modules may be connected together in a selectable manner.

### CROSS-REFERENCE TO RELATED APPLICATIONS

This application is a continuation of PCT International Application No. PCT/EP2008/006379, filed Aug. 1, 2008, which claims priority under 35 U.S.C. §119 to German Patent Application No. DE 10 2007 037 797.7, filed Aug. 10, 2007.

### FIELD OF THE INVENTION

The invention relates to an electrical connection system, and more particularly, an electrical connection system for a photovoltaic installation.

### BACKGROUND

Solar installations typically include a plurality of solar cells, which are connected together electrically in order to increase the output power of the solar installation. However, shaded solar cells absorb some of the current produced by sunlit solar cells and thereby reduce the power output by the solar installation. To prevent this, diodes are connected between the individual solar cells in such a way that the solar cells can output current but not absorb current. These diodes are conventionally housed together with the connecting leads leading to the individual solar cells in a “connection box”. To protect the diodes and connections from detrimental environmental influences, such as for example dust and moisture, the connection box is sealed, such that a predetermined ingress protection (IP) rating is achieved. The flowing currents of up to 10 Amperes heat the diodes to up to 200° C. when in operation. Due to sealing of the connection box, the heat can be only poorly dissipated outwards and uncontrollable thermal superposition and thermal transfer between the diodes may arise inside the connection box. This has a negative effect on the power of the solar installation. It is also necessary to produce separate connection boxes for different solar installations with a corresponding number of connections and diodes depending on the number of solar cells used.

### SUMMARY

The invention provides a kit having an electrical connection system for photovoltaic solar installations, which has a desired Ingress Protection (IP) rating, reliably preventing thermal transfer and superposition between the diodes and may be flexibly adapted for solar installations with a different numbers of solar cells.

The kit for an electrical connection system for photovoltaic solar installations having a plurality of solar cells each with its own electrical connection, includes a number of modules, which maybe of different types, to accommodate different components of the connection system. At least one type of module includes a connecting device being connectable to the external electrical connection of one of the solar cells and each of the modules.

### BRIEF DESCRIPTION OF THE DRAWINGS

Further details, advantages and features of this invention are given in the following description of an embodiment, in association with the drawings. In these drawings:

FIG. 1 is a plan view of an electrical connection system according to the invention;

FIG. 2 is a perspective view from above the electrical connection system from FIG. 1;

FIG. 3 is a perspective view from above of a diode module for an electrical connection system according to the invention;

FIG. 4 is a perspective view from above of a module for an electrical connection system according to the invention, which is arranged for accommodation of a sensor and a data connection;

FIG. 5 is a perspective view from above of an end module with a power connection for an electrical connection system according to the invention;

FIG. 6 is a perspective view from above of a connection module for an electrical connection system according to the invention with a connecting device for connecting a solar cell;

FIG. 7 is a perspective view from above of a blank of a module for an electrical connection system according to the invention with a receiving cavity;

FIG. 8 is a perspective view from above of a cooling module for an electrical connection system according to the invention; and

FIG. 9 shows two connecting modules for an electrical connection system according to the invention, which are closed from above with a cover

### DETAILED DESCRIPTION OF THE EMBODIMENT(S)

An embodiment of the invention will be described as follows with reference to the drawings.

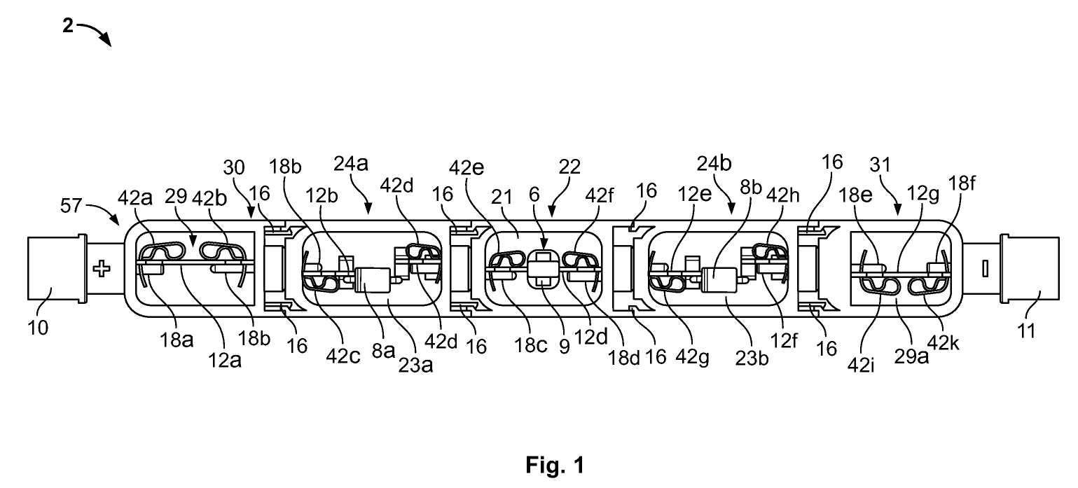

FIG. 1 shows a plan view of an electrical connection system 2 according to the invention. The connection system 2 shown in FIG. 1 includes five modules 30, 24a, 22, 24b, 31, which are arranged in a row from left to right and are each connected together in pairs at their end walls. The modules 30, 24a, 22, 24b, 31 have not as yet been closed by a cover, so as to allow a view into their inside 29, 23a, 21, 23b, 29a.

A first end module 30 includes at its end wall 57 a first power connector 10, which serves as a power output connection, for carrying the current generated by the solar cell (not shown) to a consumer unit or a current storage device. The first power connector 10 shown in FIG. 1 takes the form of a round bayonet connector. Alternatively, a screw or plug-in connector may also be provided. A first electrical conductor 18a leads from the first power connector 10 into the receiving space 29 of the first end module 30 and is there connected by a first cage clamp spring 42a to the left-hand end of a first conductor bar 12a, which extends from an end wall 57 of the receiving space 29 to a right-hand end wall of the first end module 30. There, the right-hand end of the first conductor bar 12a is connected by a second cage clamp spring 42b to a second electrical conductor 18b, which leads through the right-hand end wall of the first end module 30 into a first diode module 24a adjacent and to the right. The first conductor bar 12a takes the form of an elongate metal plate and is arranged with its broad side vertical in the receiving space 29 of the first end module 30.

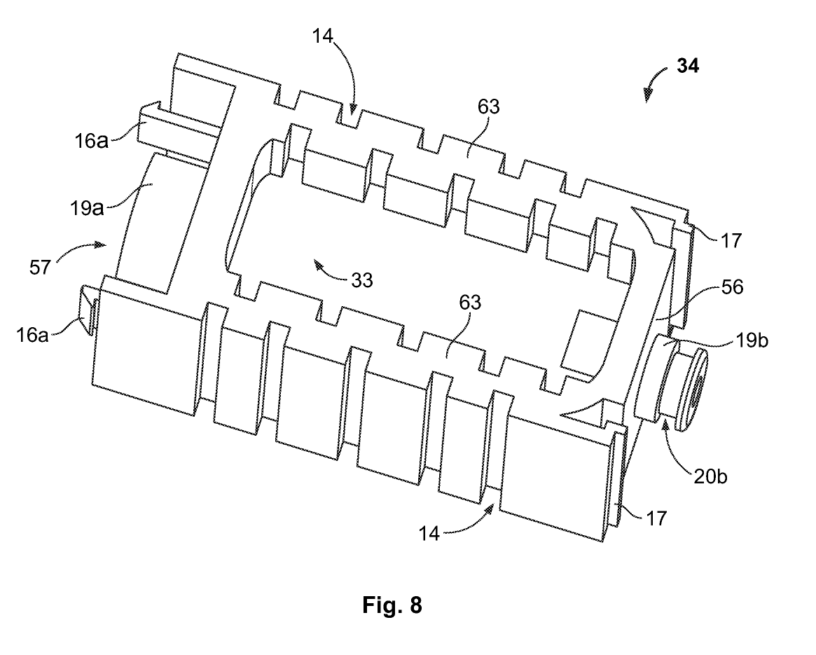

In the first diode module 24a, the second electrical conductor 18b is connected using a third cage clamp spring 42c to the left-hand end of a second conductor bar 12b. A first diode 8a connects to a right-hand end of the second conductor bar 12b, connecting at the left-hand terminal of the first diode 8a. The right-hand terminal of the first diode 8a is connected to the left-hand end of a third conductor bar 12c on the right-hand side of the receiving space 23 of the first diode module 24a. The right-hand end of the third conductor bar 12c is in turn connected by a fourth cage clamp spring 42d to a third electrical conductor 18c, which leads through the right-hand end wall of the first diode module 24a into the connection module 22 adjacent and to the right. Because the first diode module 24a contains only one diode 8a, uncontrolled thermal transfer between different diodes is reliably avoided. In order to better dissipate the heat generated by the first diode 8a, the receiving space 23 of the first diode module 24a may be filled with a thermally conductive casting compound, and/or the walls of the first diode module 24a may be provided with cooling ribs 14 (see below, FIG. 8). In the connection module 22 the third electrical conductor 18c is connected by a fifth cage clamp spring 42e to a left-hand end of a fourth conductor bar 12d, which leads from left to right through a receiving space 21 of the module 22 and is connected at its right-hand end on a right-hand side of the receiving space 21 using a sixth cage clamp spring 42f to a fourth electrical conductor 18d, which leads into a second diode module 24b adjacent and to the right. The middle area of the fourth conductor bar 12d is constructed as a connecting device 6 for connection of an electrical connection of a solar cell (not shown). The solar cell connection, which takes the form, for example, of a flexible flat cable of aluminium, is clamped to the fourth conductor bar 12d by a clamping device 9. In the embodiment shown, the clamping device 9 takes the form of an omega spring. The flexible flat cable of the solar cell is introduced through an opening, not visible in FIG. 1, in a base of the module 22 into the receiving space 21 thereof and placed around the middle area of the fourth conductor bar 12d. Then the flexible flat cable is clamped on the middle area of the fourth conductor bar 12d by pushing on the clamping device 9 (i.e. omega spring). Construction of the connecting device 6 as a clamping unit for a flexible flat cable is only an example. The connecting device 6 may also take any other form, for example it may take the form of a plug-in or screw connection.

The structure of the second diode module 24b, which is arranged to the right of the connection module 22, corresponds to the structure of the first diode module 24a, which is arranged to the left of the connection module 22. In the second diode module 24b, the fourth electrical conductor 18d is connected via a seventh cage clamp spring 42g to the left-hand end of a fifth conductor bar 12e. To the right-hand end of the fifth conductor bar 12e there is connected the left-hand terminal of a second diode 8b. The right-hand terminal of the second diode 8b is connected to the left-hand end of a sixth conductor bar 12f, which is arranged on the right-hand side of the receiving space 23b of the second diode module 24b. The right-hand end of the sixth conductor bar 12f is connected to a fifth electrical conductor 18e by an eighth cage clamp spring 42h, which leads through a right-hand end wall of the second diode module 24b into a second end module 31 adjacent and to the right.

The structure of the second end module 31 is a mirror image of the structure of the first end module 30. The fifth electrical conductor 18e introduced through the left-hand end wall 56 of the second end module 31 is connected electrically to the left-hand end of a seventh conductor bar 12g using a ninth cage clamp spring 42i. The seventh conductor bar 12g leads through the receiving space 29a of the second end module 31 and is connected at its right-hand end to a sixth electrical conductor 18f using a tenth cage clamp spring 42k. The sixth electrical conductor 18f is guided through the right-hand end wall 57 of the second end module 31 and connects the seventh conductor bar 12g electrically to a second power connector 11. The second power connector 11 of the second end module 31 serves as a power input connection, for coupling on a further connection system 2 via a cable, not shown, such that two or more electrical connection systems 2 are operated in series with the associated solar cells, in order to increase the output voltage of the system. If no provision is made for connecting a further connection system 2, the second connection is closed with an insulating plug or an end module is used which does not have a second power connector 11 but rather accommodates and insulates the fifth electrical conductor 18e of the adjacent module.

Latching connectors 16 are visible at the interfaces between the modules 30, 24a, 22, 24b, 31. The latching connectors 16 connect the modules together mechanically at their end faces and take the form, for example, of latching or plug-in connectors.

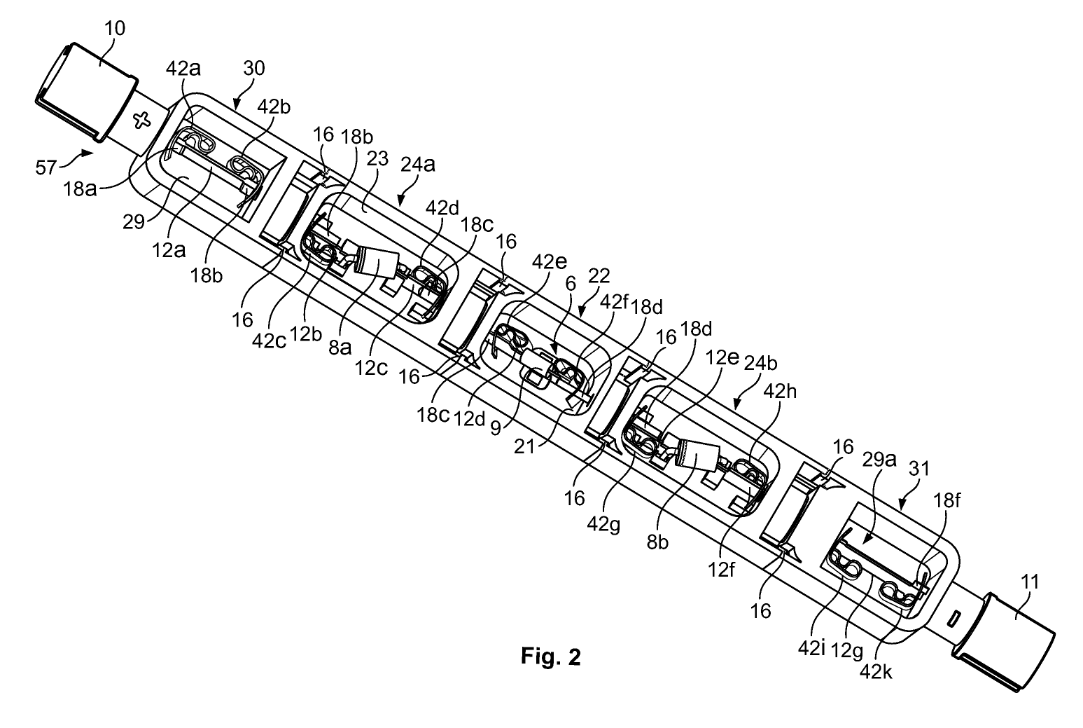

FIG. 2 shows the connection system 2 of FIG. 1 in a perspective view. The elements already illustrated in FIG. 1 and discussed in connection with FIG. 1 are provided with the same reference signs and are not discussed again.

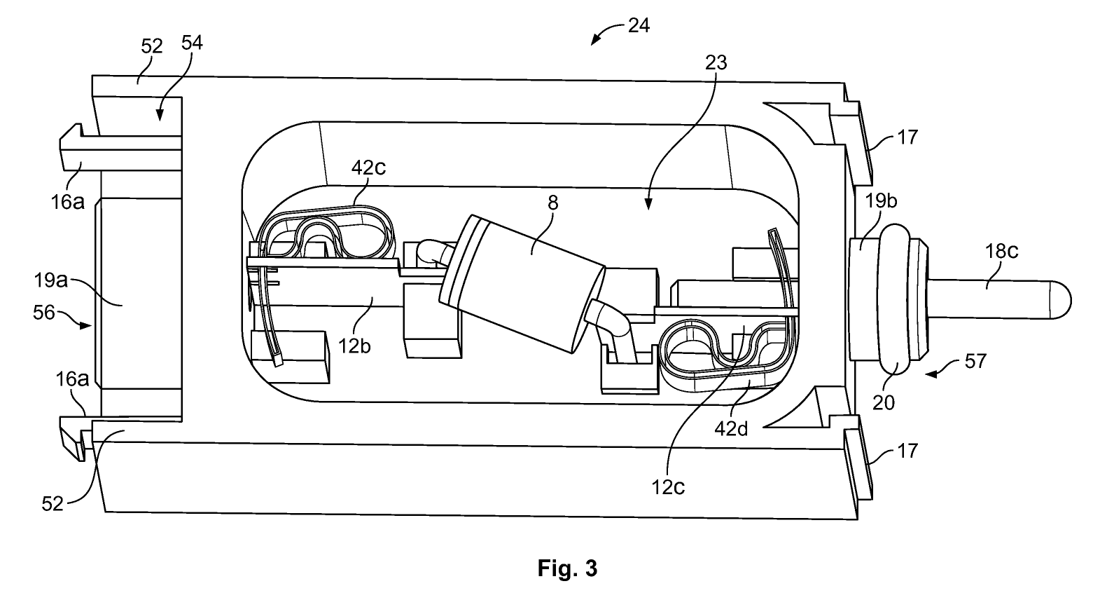

FIG. 3 shows the perspective view of a diode module 24 from above. In this view too, no cover is shown, so as to allow a view into the inside 23 of the diode module 24. In the shown embodiment, the diode module 24 is cuboid in form with an approximately square cross-section. The diode module 24 is approximately twice as long as it is wide or high. For example, the embodiment shown has a width of substantially 25 mm, a height of substantially 25 mm and a length of substantially 50 mm. At its left-hand end wall 56 the diode module 24 includes outwardly projecting, vertical side walls 52 and therebetween a notch 54, in which there are provided two latching arms 16a, each with an outwardly extending latching hook, and a round connector 19a for receiving an electrical conductor 18. Inside the diode module 24 there is formed a receiving space 23 for accommodating components of the connection system 2, such as for example a diode 8. The terminals of the diode 8 are each fastened to the ends of a second and third conductor bar 12b, 12c, each leading to the left-hand or right-hand end wall 56, 57 of the diode module 24. A third cage clamp spring 42c is located at the left-hand end of the second conductor bar 12b, which connects the second conductor bar 12b to a conductor, which is inserted through the connector 19a in the left-hand end wall 56, of an adjacent module, not shown. The third conductor bar 12c is connected at its right-hand end by a fourth cage clamp spring 42d to a third electrical conductor 18c, which leads through the right-hand end wall 57 of the diode module 24 to the outside. In the embodiment shown, the third electrical conductor 18c is round, taking the form for example of a knurled contact pin, but the pin may also be polygonal, taking the form for example of a square, hexagonal or octagonal pin.

On the right-hand end wall 57 of the diode module 24, a round connector 19b is formed around the third electrical conductor 18c guided outwards through the end wall 57, which connector 19b may be fitted into the connector 19a of an adjacent module, not shown. Around the circumference of the connector 19b there is arranged an O-ring 20, for sealing the connection between the connector 19a and the connector 19b of an adjacent module.

On both sides of the right-hand end wall 57 of the diode module 24, at the outside, there are formed two projections 17, which extend over the entire height of the end wall 57 from top to bottom. The latching hooks of the latching arms 16a of an adjacent module may engage these projections 17, in order to connect the modules together. In an alternative embodiment, not shown, the projections 17 are not formed over the entire height of the end wall 57 of the diode module 24, but rather only at the level of the latching arms 16a.

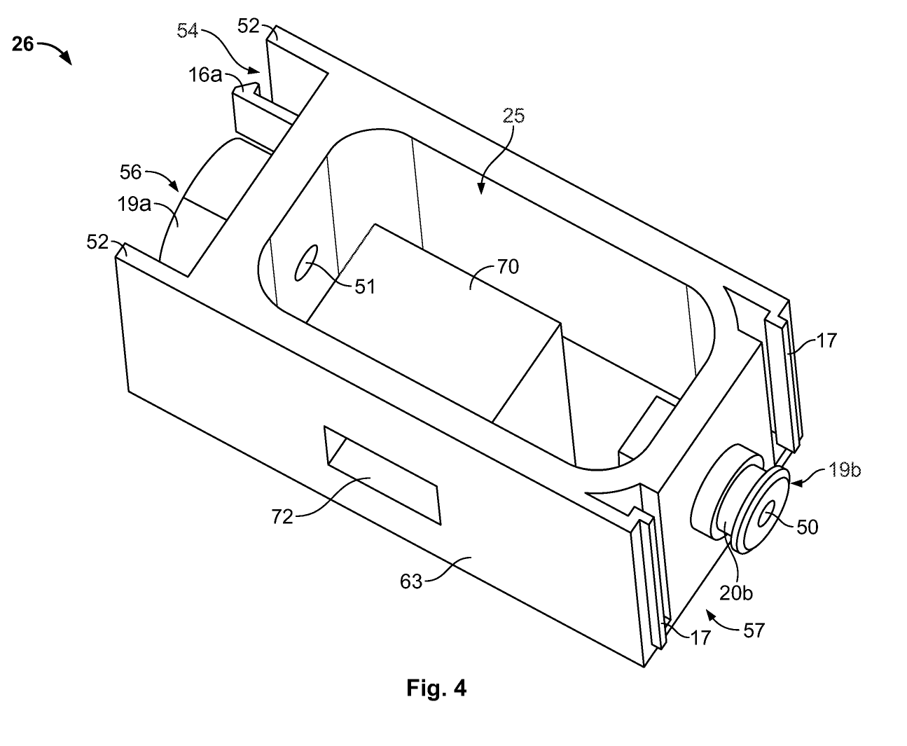

FIG. 4 shows a sensor module 26 for a sensor, where no cover is shown, so as to allow a view into the receiving space 25 of the sensor module 26. The outer structure of the sensor module 26 corresponds to the diode module 24 shown in FIG. 3. In the receiving space 25 of the sensor module 26 there is provided a receiving box 70 for receiving a sensor, for example a temperature or theft sensor. The inside of the receiving box 70 is accessible from the outside through an sensor passageway 72 in the side wall 63 of the sensor module 26. A data connection may, for example, be introduced into the sensor passageway 72, in order to output to the outside the data generated by a sensor introduced into the receiving box 70 and/or to control the sensor by signals supplied from outside. In the embodiment shown in FIG. 4, no conductor bar is shown in the receiving space 25 of the sensor module 26. Depending on the type of sensor positioned in the receiving box 70, a conductor bar 12 is guided around the receiving box 70 in the inside 25 of the sensor module 26 if the sensor does not need any contact with the conductor bar 12, for example if the sensor is provided for measuring the temperature of the solar cells. The conductor bar 12 is guided through the receiving box 70, if the sensor is provided, for example, for measuring the current flowing through the conductor bar 12. As in the diode module 24 shown in FIG. 3, the conductor bar 12g is connected using cage clamp springs, not shown, to electrical conductors, not shown, which are guided outwards through conductor receiving passageways 50, 51 in the end walls 56, 57 of the sensor module 26.

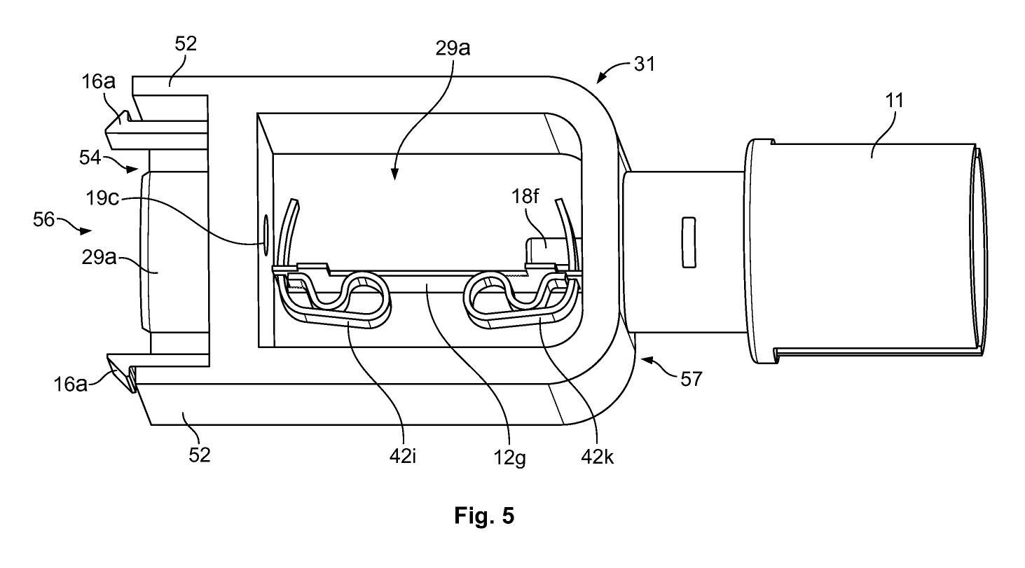

FIG. 5 shows a perspective view of an second end module 31 with a second power connector 11, where the cover has been removed, to allow a view of the inside 29a of the second end module 31. The outer dimensions and the structure of the left-hand end wall 56 correspond to the diode module 24 shown in FIG. 3. In the embodiment shown in FIG. 5 of the second end module 31, the corners of the right-hand end wall 57 are rounded, but this is only an exemplary configuration and is not absolutely necessary. In the inside 29a of the second end module 31, a seventh conductor bar 12g extends from left to right. At the left-hand end of the seventh conductor bar 12g there is provided a ninth cage clamp spring 42i, for electrically connecting the first conductor bar 12a to a pin, not shown in FIG. 5 and inserted through the connector 19a and a connector receiving passageway 19c in the left-hand end wall 56, of an adjacent module not shown in FIG. 5. A tenth cage clamp spring 42k is provided at the right-hand end of the seventh conductor bar 12g. The tenth cage clamp spring 42k connects the seventh conductor bar 12g to a sixth electrical conductor 18f, which is guided outwards through the right-hand end wall 57 and connects the seventh conductor bar 12g electrically to the second power connector 11, which is mounted on the outside of the right-hand end wall 57. The second power connector 11 shown in FIG. 5 is a round bayonet connector, but a screw or plug-in connection may alternatively be used. The second power connector 11 may take the form of a plug (“male”) or socket (“female”). The second power connector 11 serves either as a power output connection for the purpose of carrying current generated by the solar cells, not shown, to a consumer unit or a current storage device, or as a power input connection for the purpose of coupling on a further connection system 2 through a cable, not shown. Thus, a plurality of electrical connection systems 2 may be connected in series, in order to increase the output voltage of the overall system.

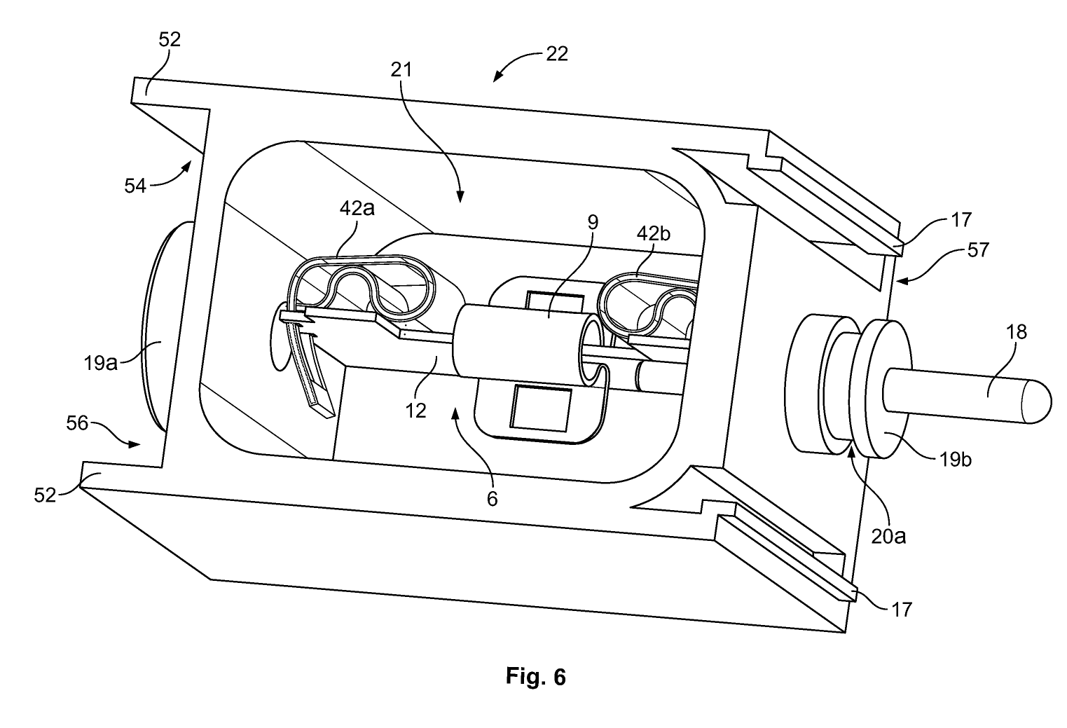

FIG. 6 shows a perspective view of a connection module 22 for connection of a solar cell, not shown. The outer dimensions, and the structure of the left-hand end wall 56 and the right-hand end wall 57, correspond to those of the diode module 24 shown in FIG. 3, wherein in the perspective shown in FIG. 6 the latching arms 16a are invisible, but nevertheless present at the left-hand end wall 56 of the connection module 22. The connector 19b on the right-hand end wall 57 of the connection module 22 has not yet been provided with an o-ring 20. Instead, a receiving groove 20a is visible, which is formed in the circumference of the connector 19b for receiving such an o-ring 20.

In the receiving space 21 of the connection module 22 a conductor bar 12 extends from left to right. At its left-hand end, the conductor bar 12 is provided with a first cage clamp spring 42a, for connecting the conductor bar 12 to an electrical conductor 18, inserted through the connector 19a on the left-hand end wall 56 of the module 22, of an adjacent module, not shown in FIG. 6. At its right-hand end, the conductor bar 12 is provided with a second cage clamp spring 42b, which connects the conductor bar 12 to an electrical conductor 18, which is guided outwards through the right-hand end wall 57 and the connector 19b mounted on the outside of this end wall 57, in order to connect the module 22 electrically to an adjacent module. The middle area of the conductor bar 12 takes the form of a connecting device 6 for connection of a solar cell, not shown in FIG. 6. In the embodiment shown in FIG. 6, this connecting device 6 takes the form of a clamping device 9, i.e. an omega spring. The connecting cable of the solar cell, which takes the form of a flexible flat cable, is introduced through an opening not visible in FIG. 6 in the base of the connection module 22 into the receiving space 21 thereof and placed around the conductor bar 12. Then the clamping device 9 (i.e. omega spring) is pushed from above onto the conductor bar 12, in order to clamp the flexible flat cable on the conductor bar 12. Such a clamping device 9 provides a connection which is simple to produce but nevertheless secure between the connecting cable and the conductor bar 12. Construction of the connecting device 6 for a flexible flat cable is only an example, however. The connecting device 6 may also take another form, for example that of a plug-in or screw connection.

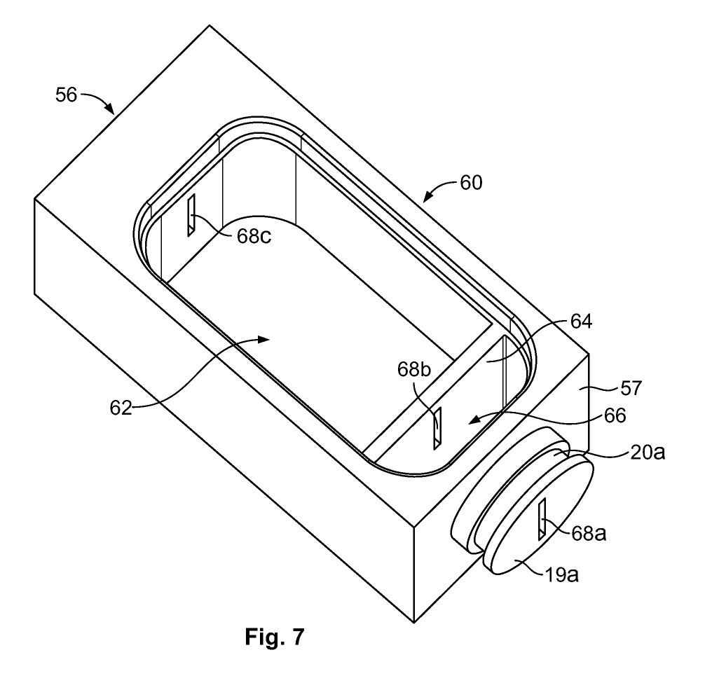

With reference to FIG. 7, a blank 60 for a module of an electrical connection system 2 is shown having outer dimensions corresponding to those of the previously illustrated modules. This blank 60 too is not provided with a cover, so as to allow a view into the inside 62 of the blank 60.

In the middle of its right-hand end wall 57, the blank 60 is provided with a connector 19a. The connector 19a is round and has a receiving groove 20a in its circumference for accommodating an O-ring, not shown. A first receiving passageway 68a is formed in the connector 19a and the end wall 57 located behind it, for guiding a conductor bar or a conductor from the outside into the inside 62 of the blank 60. In the embodiment shown in FIG. 7, the first receiving passageway 68a takes the form of a vertical slot. The first receiving passageway 68a may, however, also be constructed as a horizontal slot, square or round opening.

In the receiving space 62 of the blank 60 an inner dividing wall 64 is provided at a distance from the right-hand end wall 57, for dividing off an area, receiving cavity 66, of the receiving space 62. This receiving cavity 66 may be filled, for example with an insulating casting compound, to seal the receiving space 62 against the penetration of dust, moisture and/or the like through the first receiving passageway 68a. A second receiving passageway 68b is provided in the dividing wall 64, for guiding a conductor or a conductor bar from the first receiving passageway 68a on into the receiving space 62 of the blank 60.

In the left-hand end wall 56 of the receiving space 62 a third receiving passageway 68c is provided, for guiding a conductor, an electrical conductor or a conductor bar from the receiving space 62 through the left-hand end wall 56 to the outside.

The embodiment shown in FIG. 7 is shown only by way of example, for instance, a second dividing wall 64 may be provided in the left-hand area of the receiving space 62, in order there to form a second receiving cavity 66 for accommodating an insulating casting compound, in order also to seal the third receiving passageway 68c.

FIG. 8 shows a perspective view of a cooling module 34, with the structure of the end walls 56, 57 of the cooling module 34 corresponding to the end walls 56, 57 of the sensor module 26 shown in FIG. 4. The side walls 63 of the cooling module 34 are each provided on their inner and outer sides with cooling ribs 14. These cooling ribs 14 allow heat, which is generated by components, not shown, connected in the receiving space 33 of the cooling module 34, to be effectively dissipated to the outside. A diode, a sensor and/or a conductor bar, for example, may be fitted in a cooling module 34.

In a further embodiment, not shown, the cooling ribs 14 are constructed such that laterally adjacent cooling modules 34 are connectable together by inserting the cooling ribs 14 in one another, such that the cooling modules 34 are connectable together not only in the longitudinal direction, but also in the transverse direction. In particular, the cooling ribs 14 may be constructed for this purpose having a dovetailed profile. In a further embodiment, which is not shown, cooling ribs 14 may be formed on the top and/or bottom of the cooling module 34, such that the modules may be connected together mechanically in all three dimensions.

In another embodiment, which is not shown, the modules are provided, irrespective of the cooling ribs 14, with connecting elements on the side walls and/or on the top or bottom, such that the modules may be connected together in two or three dimensions.

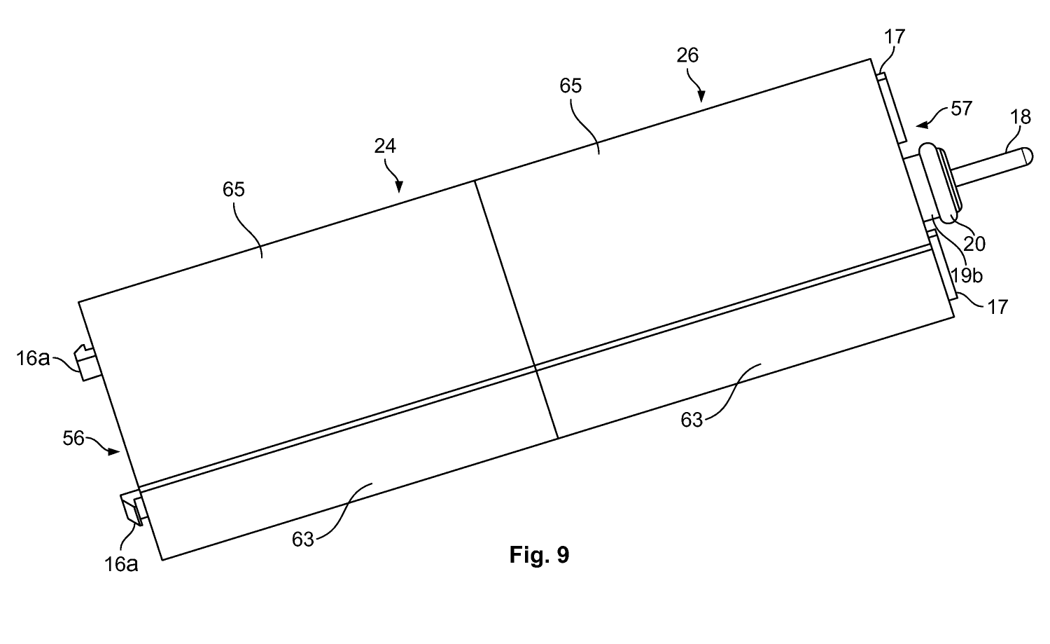

With reference to FIG. 9, two modules, the diode and sensor modules 24, 26 are shown, being connected together by a latching connector 16 (not visible). The two modules, the diode and sensor modules 24, 26 have each been closed in leakproof manner by a cover 65, such that the components fitted in the modules, the diode and sensor modules 24, 26 are protected, in accordance with a predetermined IP rating, from external influences, such as for example moisture or dust. Further modules may be attached to the respective end walls 56, 57 using the projections 17 provided on the right-hand end wall 57 of the sensor module 26 or the latching arms 16a provided on the left-hand end wall 56 of the diode module 24. An electrical connection to a further module, mounted on the right-hand end wall 57, is produced using the electrical conductor 18 in the right-hand end wall 57 of the sensor module 26. The O-ring 20 mounted on the connector 19b seals the connection in watertight manner. At the left-hand end wall 56 of the diode module 24 there is provided a connector 19a, not visible, for accommodating a connector 19b and an electrical conductor 18 of an adjacent module and so producing a further electrical connection.

A kit according to the invention may include the aforementioned electrical connection system 2 with use for photovoltaic solar installations. The kit would includes a plurality of solar cells each with their own electrical connection system 2.

With such a modular kit, the electrical connection system 2 may be individually assembled according to particular requirements, in particular in accordance with the number of solar cells used in the solar installation. Because the different components of the connection system 2 are accommodated in each case in a separate module (30, 24a, 22, 24b, 31), uncontrolled thermal superposition and thermal transfer between the components is reliably avoided. Since each of the modules 30, 24a, 22, 24b, 31 is in itself smaller than a conventional connection box, it may be more readily sealed, in order to achieve the desired IP protection rating.

In another embodiment, the kit includes a type of module (30, 24a, 22, 24b, 31), which is designed for connection of a component selected from a diode, a temperature sensor and a theft sensor. Because each such module (30, 24a, 22, 24b, 31) contains at most one diode, uncontrolled thermal transfer between the diodes is prevented. Dissipation of heat may thus be controlled and the module (30, 24a, 22, 24b, 31) designed accordingly.

The temperature of the solar cells may be monitored using a temperature sensor. To this end, the electrical connection system 2 is fastened directly to the solar cells. If a temperature sensor is included in a module (30, 24a, 22, 24b, 31) together with a diode, the operating temperature of the diode may also be monitored. Using a theft sensor, which for example detects unusual vibration of the solar system or a sudden interruption of the electric circuit, an attempt to steal the solar cell and/or modules 30, 24a, 22, 24b, 31 may be identified early, such that a corresponding alarm may be triggered.

In a further embodiment, the kit comprises a type of modules (30, 31) having with a power connection or a data connection. Current generated by the solar cells may be carried from the connection system to a consumer unit or a storage device through the power connection. Alternatively, current may be supplied by a further connection system, in order to increase the output of the overall system. Data produced by the temperature sensor or the theft sensor may be transmitted through a data connection for further evaluation and processing. The data connection may be an analogue or a digital data connection; in particular it may be an RJ45 connection.

In one embodiment, the modules 30, 24a, 22, 24b, 31 are produced, at least in part, using an injection molding method. An injection molding method enables simple and inexpensive production of the modules 30, 24a, 22, 24b, 31. In a further embodiment, the modules 30, 24a, 22, 24b, 31 have a uniform outer structure, such that they may be produced inexpensively with a single injection mold.

Besides these, the configurations described in the above-described embodiment can be selected optionally or can be changed appropriately in to other configurations without departing from the spirit and scope of the present invention.

What is claimed is:

1. A kit for an electrical connection system for photovoltaic solar installations having a plurality of solar cells each with its own electrical connection, comprising:
a number of different modules for accommodating different components of the connection system;
wherein at least one type of module includes a connecting device for connection of the external electrical connection of one of the solar cells and each of the modules.

2. The kit according to claim 1, wherein the connecting device comprises a clamping device for clamping the electrical connection in place.

3. The kit according to claim 2, wherein one of the modules is designed for connection of a component selected from the group of a diode, a temperature sensor and a theft sensor.

4. The kit according to claim 1, wherein one of the modules connects a component selected from the group of a diode, a temperature sensor and a theft sensor.

5. The kit according to claim 4, wherein one of the modules has a connection selected from a group comprising a data connector and a power connector.

6. The kit according claim 5, wherein one of the modules has at least one conductor bar.

7. The kit according to claim 1, wherein one of the modules has cooling ribs.

8. The kit according to claim 1, wherein one of the modules is filled at least in part with a casting compound.

9. The kit according to claim 8, wherein the casting compound is a thermally conductive casting compound.

10. The kit according to claim 1, wherein one of the modules has at least one latching connector for connecting adjacent modules together mechanically.

11. The kit according to claim 1, wherein one of the modules has at least one electrical conductor for connecting adjacent modules together electrically.

12. The kit according to claim 11, wherein one of the modules has at least one O-ring for watertight sealing of the electrical connector.

13. The kit according to claim 1, wherein one of the modules is closed using a leakproof cover.

14. The kit according to claim 1, wherein the modules are injection molded.

15. A module for an electrical connection system for photovoltaic solar installations having a plurality of solar cells each with its own electrical connection, comprising:
a selectable component of the connection system accommodated in the module;
wherein the module is connectable to other modules of the kit.

16. The module according to claim 15, wherein the module includes a connecting device for connecting an electrical connection of a solar cell.

17. The module according to claim 16, wherein the connecting device comprises a clamping device for clamping the electrical connection in place.

18. The module according to claim 17, wherein the module includes a component selected from the group comprising a diode, a temperature sensor and a theft sensor.

19. The module according to claim 15, wherein the module includes a component selected from the group comprising a diode, a temperature sensor and a theft sensor.

20. The module according to claim 15, wherein the module includes a connection selected from the group comprising a power connector and a data connector.

21. The module according to any one of claims 15, wherein the module is constructed with a connection selected from the group comprising a power connector and a data connection.

22. The module according to claim 15, wherein the module is provided with at least one conductor bar.

23. The module according to claim 15, further comprising cooling ribs.

24. The module according to claim 15, wherein the module is filled at least in part with a casting compound.

25. The module according to claim 24, wherein the casting compound is a thermally conductive casting compound.

26. The module according to claim 15, further comprising at least one latching connector for mechanical connection to at least one further module.

27. The module according to claim 15, further comprising at least one electrical conductor for electrical connection to at least one further module.

28. The module according to claim 27, further comprising at least one O-ring for watertight sealing of the electrical connector.

29. The module according to claim 15, wherein the module is closed using a leakproof cover.

30. The module according to claim 15, wherein the module is injection molded.
